(19) United States
(12) Patent Application Publication
(10) Pub. No.: US 2026/0033384 A1
(43) Pub. Date: Jan. 29, 2026

(54) METHODS AND SYSTEMS FOR CONTROLLING HEIGHTS OF DEVICE PACKAGES

(71) Applicant: SK Hynix NAND Product Solutions Corp. (dba Solidigm), Rancho Cordova, CA (US)

(72) Inventor: Bilal KHALAF, Folsom, CA (US)

(21) Appl. No.: 18/782,434

(22) Filed: Jul. 24, 2024

(51) Int. Cl. H01L 25/065; H01L 21/48; H01L 23/00; H01L 23/13; H01L 23/498; H10B 80/00

(52) U.S. Cl. CPC H01L 25/0657; H01L 21/4853; H01L 23/13; H01L 23/49827; H01L 24/48; H10B 80/00; H01L 2224/48147; H01L 2224/48227; H01L 2225/0651; H01L 2225/06548; H01L 2225/06562; H01L 2924/1438; H01L 2924/1815

(57) ABSTRACT

This application is directed to packaging technology for providing an electronic device (e.g., a memory device). A memory device includes a stack of memory chips, a device substrate, and a conductive wire. The stack of memory chips includes a first memory chip having a chip pad that is formed on a surface of the first memory chip. The device substrate includes a plurality of substrate pads formed on a front surface of the device substrate. The front surface has a front opening, and the device substrate receives the stack of memory chips via the front opening of the front surface. The conductive wire is coupled to the front surface and the stack of memory chips, and is configure to couple the chip pad and one of the substrate pads electrically. In some embodiments, the device substrate includes a cutout opening that goes through an entire thickness of the device substrate.

### TECHNICAL FIELD

This application relates generally to packaging technology for an electronic device (e.g., a memory device) including, but not limited to, integrating or assembling a plurality of integrated circuit dies or chips (e.g., NAND flash memory chips in a solid-state drive (SSD)) in a package of the electronic device.

### BACKGROUND

Memory is applied in a computer system to store instructions and data. The data are processed by one or more processors of the computer system according to the instructions stored in the memory. Multiple memory units are used in different portions of the computer system to serve different functions. Specifically, the computer system includes non-volatile memory that acts as secondary memory to keep data stored thereon if the computer system is decoupled from a power source. Examples of the secondary memory include, but are not limited to, hard disk drives (HDDs) and solid-state drives (SSDs). As the storage capacity of SSDs increases, multiple NAND flash memory chips are packed into a single SSD package, creating significant challenges on thermal management, power consumption, physical space constraints, signal integrity, manufacturing complexity, reliability, and firmware/software complexity. Manufacturers must design compact, high-density packaging solutions without compromising the integrity and performance of the SSD. Particularly, a printed circuit board (PCB) design must accommodate additional chips, controllers, and other components within a limited area.

### SUMMARY

Various embodiments of this application are directed to methods, systems, devices for providing a package that integrates or assembles a plurality of integrated circuit (IC) dies or chips (e.g., NAND flash memory chips in a solid-state drive (SSD)). In accordance with at least some embodiments disclosed herein is the realization that, when stacked on top of a substrate, memory chips of a memory device can hit a limit on a stack height defined by a dimension of a package in which the memory device is enclosed. In some embodiments of this application, the substrate of the memory device includes a recess or a cutout opening, and a stack of memory chips partially sinks below a front surface of the substrate while keeping space for wire accesses from the substrate to the memory chips in the stack. Stated another way, the stack of memory chips sits onto the recess or is suspended in the cutout opening of the substrate. One or more wires are mechanically and electrically coupled between the substrate and at least a subset of memory chips. In some embodiments, a carrier (e.g., made of a glass, a molten structure) is temporarily applied to assemble the stack of memory chips to the substrate.

In some embodiments, a space corresponding to at least part of a height of the substrate can be saved in the package of the memory device, creating a height saving of the package. The height saving corresponds to a depth of the recess or a thickness of the substrate, and determines how many memory chips sink within the recess or overlap the thickness of the substrate in the cutout opening. By these means, the height saving allows more chips to be added on the stack and assembled into the package, thereby increasing the storage capacity of the memory device (e.g., SSDs applied in compact electronic devices).

In one aspect, a memory device includes a stack of memory chips, a device substrate, and a conductive wire. The stack of memory chips includes a first memory chip, and the first memory chip further includes a chip pad formed on a first surface of the first memory chip. The device substrate includes a plurality of substrate pads, and the plurality of substrate pads are formed on a front surface of the device substrate, and the front surface has a front opening. The device substrate receives the stack of memory chips via the front opening of the front surface. The conductive wire is coupled to the front surface and the stack of memory chips, and is configure to couple the chip pad and one of the plurality of substrate pads electrically.

In some embodiments, the device substrate includes a recess having a top edge defined by the front opening of the front surface, and the stack of memory chips are partially disposed in the recess. Further, in some embodiments, the first memory chip sits on, and contacts, a bottom surface of the recess.

In some embodiments, the device substrate includes a cutout opening that goes through an entire thickness of the device substrate and has a top edge defined by the front opening of the front surface, and the stack of memory chips is disposed in the cutout opening and surrounded by the device substrate.

In another aspect, a memory device includes a stack of memory chips, a device substrate, and a first conductive wire. The stack of memory chips includes a first memory chip and a remainder of the stack. The first memory chip has a first surface on which the remainder of the stack is mechanically coupled, and the first surface of the first memory chip includes a conductive chip pad. The device substrate has a front surface and a rear surface opposing the front surface, and the front surface has a cutout opening for receiving the stack of memory chips. The front surface of the device substrate includes a plurality of conductive substrate pads surrounding the cutout opening of the front surface. The first conductive wire coupled to both the front surface and the stack of memory chip. The first conductive wire is attached to the conductive chip pad of the first memory chip and one of the plurality of conductive substrate pads of the device substrate. A thickness of the device substrate at least partially overlaps a thickness of the stack of memory chips, and a footprint of the stack of the memory chips at least partially overlaps the cutout opening of the front surface of the device substrate.

In another aspect of the application an electronic device includes a stack of semiconductor chips including a first chip, a device substrate including a plurality of substrate pads. The first chip further includes a chip pad formed on a first surface of the first chip, and a conductive wire coupled to the front surface and the stack of semiconductor chips. The plurality of substrate pads are formed on a front surface of the device substrate, and the front surface has a front opening. The device substrate receives the stack of semiconductor chips via the front opening of the front surface. The conductive wire is configure to couple the chip pad and one of the plurality of substrate pads electrically.

In another aspect, a method is implemented to provide a memory device. The method includes providing a device substrate including a plurality of substrate pads, and the plurality of substrate pads are formed on a front surface of the device substrate, and the front surface has a front opening. The method further includes removing a portion of a device substrate to create one of a recess and a cutout opening and providing a stack of chips including a first chip. The first chip further includes a chip pad formed on a first surface of the first chip. The method further includes receiving the stack of memory devices via the front opening of the front surface to partially fill the portion of the removed portion of the device substrate and applying a conductive wire to couple the chip pad of the first chip and one of the plurality of substrate pads of the device substrate.

In yet another aspect, a method is implemented to provide a memory device. The method includes providing a stack of memory chips including a first memory chip. The first memory chip further includes a chip pad formed on a first surface of the first memory chip. The method further includes providing a device substrate including a plurality of substrate pads. The plurality of substrate pads are formed on a front surface of the device substrate, and the front surface has a front opening, and wherein the device substrate receives the stack of memory chips via the front opening of the front surface. The method further includes providing a conductive wire coupled to the front surface and the stack of memory chips. The conductive wire is configure to couple the chip pad and one of the plurality of substrate pads electrically.

These illustrative embodiments and implementations are mentioned not to limit or define the disclosure, but to provide examples to aid understanding thereof. Additional embodiments are discussed in the Detailed Description, and further description is provided there.

### BRIEF DESCRIPTION OF THE DRAWINGS

For a better understanding of the various described implementations, reference should be made to the Detailed Description below, in conjunction with the following drawings in which like reference numerals refer to corresponding parts throughout the figures.

FIG. 1 is a block diagram of an example system module in a typical electronic device, in accordance with some embodiments.

FIG. 2 is a block diagram of a memory system of an example electronic device having one or more memory access queues, in accordance with some embodiments.

FIG. 3A is a perspective view of a device substrate having a cutout opening for receiving a stack of memory chips, in accordance with some embodiments, and FIG. 3B is a side view of a memory device that is formed based on the device substrate shown in FIG. 3A, in accordance with some embodiments.

FIG. 4 is a cross sectional view of a memory module that includes a device substrate having a recess for receiving a stack of memory chips, in accordance with some embodiments.

FIGS. 5A, 5B, and 5C are a cross sectional view, a top perspective view, and a bottom perspective view of an example interface region of a memory device, in accordance with some embodiments, respectively.

FIG. 6 illustrates an example process of protecting a memory device with a molding component, in accordance with some embodiments.

FIG. 7 is a flow diagram of an example process of forming a memory device having a cutout opening, in accordance with some embodiments.

FIG. 8 is a flow diagram of an example method 800 for providing a memory device, in accordance with some embodiments.

Like reference numerals refer to corresponding parts throughout the several views of the drawings.

### DETAILED DESCRIPTION

Reference will now be made in detail to specific embodiments, examples of which are illustrated in the accompanying drawings. In the following detailed description, numerous non-limiting specific details are set forth in order to assist in understanding the subject matter presented herein. But it will be apparent to one of ordinary skill in the art that various alternatives may be used without departing from the scope of claims and the subject matter may be practiced without these specific details. For example, it will be apparent to one of ordinary skill in the art that the subject matter presented herein can be implemented on many types of electronic devices using secondary storage.

Various embodiments of this application are directed to methods, systems, and devices for integrating a plurality of integrated circuit (IC) dies or chips (e.g., memory chips). A substrate of a memory device includes a recess or a cutout opening, and a stack of memory chips partially sinks below a front surface of the substrate while keeping space for wire accesses from the substrate to the memory chips in the stack. The stack of memory chips sits onto the recess or is suspended in the cutout opening of the substrate. One or more wires are mechanically and electrically coupled between the substrate and at least a subset of memory chips. In some embodiments, a carrier (e.g., made of a glass, a molten structure) is temporarily applied to assemble the stack of memory chips to the substrate. In some embodiments, a space corresponding to at least part of a height of the substrate can be saved in the package of the memory device, creating a height saving of the package. The height saving corresponds to a depth of the recess or a thickness of the substrate, and determines how many memory chips sink within the recess or overlap the thickness of the substrate in the cutout opening. By these means, the height saving allows more chips to be added on the stack and assembled into the package, thereby increasing the storage capacity of the memory device (e.g., SSDs applied in compact electronic devices).

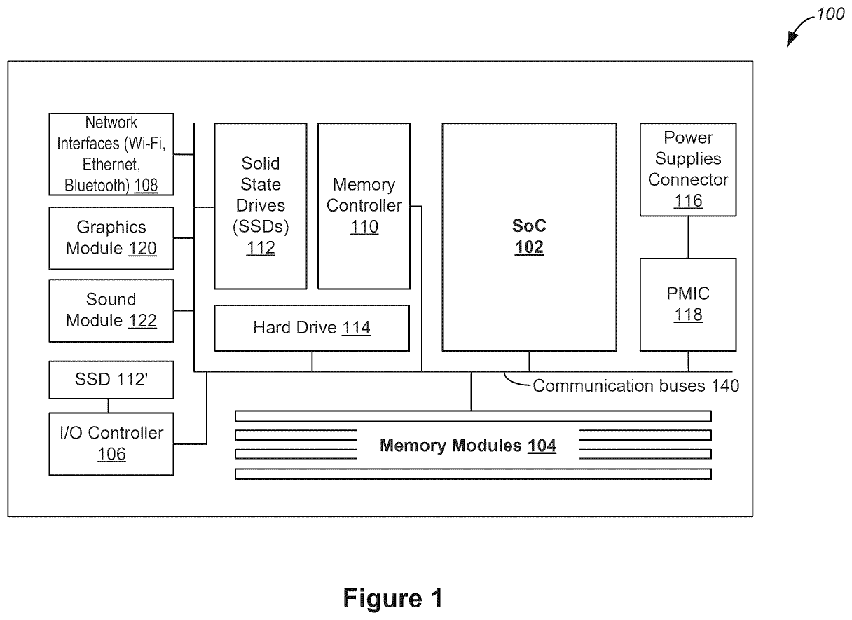

FIG. 1 is a block diagram of an example system module 100 in a typical electronic system in accordance with some embodiments. The system module 100 in this electronic system includes at least a processor module 102, memory modules 104 for storing programs, instructions and data, an input/output (I/O) controller 106, one or more communication interfaces such as network interfaces 108, and one or more communication buses 140 for interconnecting these components. In some embodiments, the I/O controller 106 allows the processor module 102 to communicate with an I/O device (e.g., a keyboard, a mouse or a trackpad) via a universal serial bus interface. In some embodiments, the network interfaces 108 includes one or more interfaces for Wi-Fi, Ethernet and Bluetooth networks, each allowing the electronic system to exchange data with an external source, e.g., a server or another electronic system. In some embodiments, the communication buses 140 include circuitry (sometimes called a chipset) that interconnects and controls communications among various system components included in system module 100.

In some embodiments, the memory modules 104 include high-speed random-access memory, such as static random-access memory (SRAM), double data rate (DDR) dynamic random-access memory (DRAM), or other random-access solid state memory devices. In some embodiments, the memory modules 104 include non-volatile memory, such as one or more magnetic disk storage devices, optical disk storage devices, flash memory devices, or other non-volatile solid state storage devices. In some embodiments, the memory modules 104, or alternatively the non-volatile memory device(s) within the memory modules 104, include a non-transitory computer readable storage medium. In some embodiments, memory slots are reserved on the system module 100 for receiving the memory modules 104. Once inserted into the memory slots, the memory modules 104 are integrated into the system module 100.

In some embodiments, the system module 100 further includes one or more components selected from a memory controller 110, SSD(s) 112, an HDD 114, power management integrated circuit (PMIC) 118, a graphics module 120, and a sound module 122. The memory controller 110 is configured to control communication between the processor module 102 and memory components, including the memory modules 104, in the electronic system. The SSD(s) 112 are configured to apply integrated circuit assemblies to store data in the electronic system, and in many embodiments, are based on NAND or NOR memory configurations. The HDD 114 is a conventional data storage device used for storing and retrieving digital information based on electromechanical magnetic disks. The power supply connector 116 is electrically coupled to receive an external power supply. The PMIC 118 is configured to modulate the received external power supply to other desired DC voltage levels, e.g., 5V, 3.3V or 1.8V, as required by various components or circuits (e.g., the processor module 102) within the electronic system. The graphics module 120 is configured to generate a feed of output images to one or more display devices according to their desirable image/video formats. The sound module 122 is configured to facilitate the input and output of audio signals to and from the electronic system under control of computer programs.

Alternatively or additionally, in some embodiments, the system module 100 further includes SSD(s) 112′ coupled to the I/O controller 106 directly. Conversely, the SSDs 112 are coupled to the communication buses 140. In an example, the communication buses 140 operates in compliance with Peripheral Component Interconnect Express (PCIe or PCI-E), which is a serial expansion bus standard for interconnecting the processor module 102 to, and controlling, one or more peripheral devices and various system components including components 110-122.

Further, one skilled in the art knows that other non-transitory computer readable storage media can be used, as new data storage technologies are developed for storing information in the non-transitory computer readable storage media in the memory modules 104, SSD(s) 112 or 112′, and HDD 114. These new non-transitory computer readable storage media include, but are not limited to, those manufactured from biological materials, nanowires, carbon nanotubes and individual molecules, even though the respective data storage technologies are currently under development and yet to be commercialized.

Some implementations of this application are directed to an integrity check process implemented by a memory system (e.g., SSD(s) 112, memory module 104, HDD 114, memory controller 110), which stores codeword symbols including integrity data, e.g., LDPC codes. The integrity check process is also called a decoding process implementing between variable nodes and check nodes. The variable nodes correspond to the codeword symbols extracted from the memory system. Each check node correspond to a distinct set of variable nodes, and has check node data configured to identify bit errors in the codeword symbols corresponding to the distinct set of variable nodes.

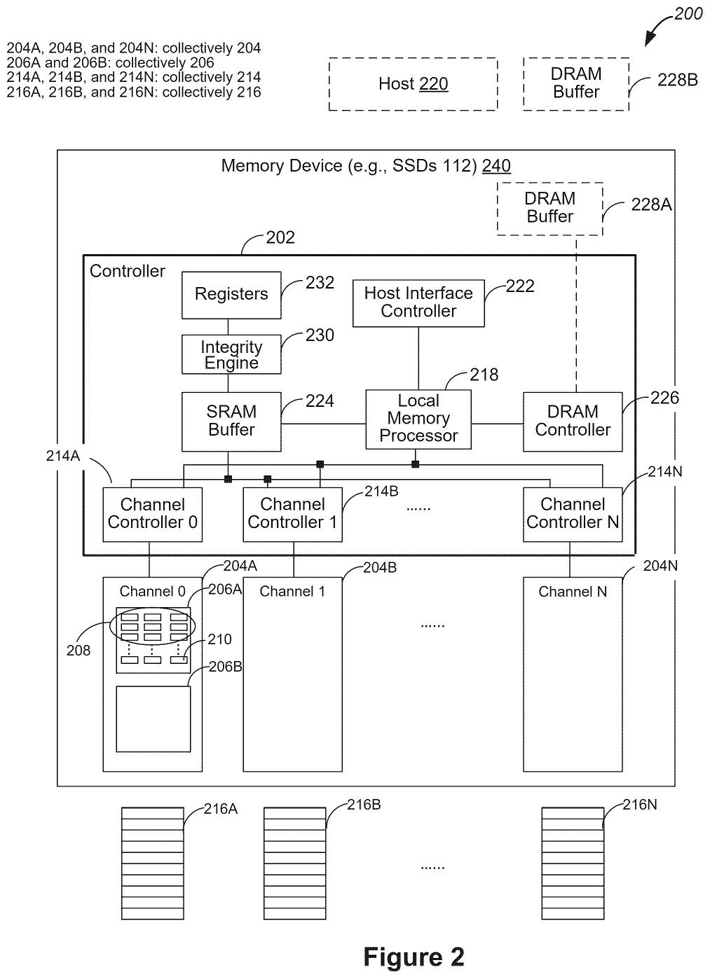

FIG. 2 is a block diagram of a memory system 200 of an example electronic device having one or more memory access queues, in accordance with some embodiments. The memory system 200 is coupled to a host device 220 (e.g., a processor module 102 in FIG. 1) and configured to store instructions and data for an extended time, e.g., when the electronic device sleeps, hibernates, or is shut down. The host device 220 is configured to access the instructions and data stored in the memory system 200 and process the instructions and data to run an operating system and execute user applications. The memory system 200 includes one or more memory devices 240 (e.g., SSD(s)). Each memory device 240 further includes a controller 202 and a plurality of memory channels 204 (e.g., channel 204A, 204B, and 204N). Each memory channel 204 includes a plurality of memory cells. The controller 202 is configured to execute firmware level software to bridge the plurality of memory channels 204 to the host device 220. In some embodiments, each memory device 240 is formed on a printed circuit board (PCB).

Each memory channel 204 includes on one or more memory packages 206 (e.g., two memory dies). In an example, each memory package 206 (e.g., memory package 206A or 206B) corresponds to a memory die. Each memory package 206 includes a plurality of memory planes 208, and each memory plane 208 further includes a plurality of memory pages 210. Each memory page 210 includes an ordered set of memory cells, and each memory cell is identified by a respective physical address. In some embodiments, the memory device 240 includes a plurality of superblocks. Each superblock includes a plurality of memory blocks each of which further includes a plurality of memory pages 210. For each superblock, the plurality of memory blocks are configured to be written into and read from the memory system via a memory input/output (I/O) interface concurrently. Optionally, each superblock groups memory cells that are distributed on a plurality of memory planes 208, a plurality of memory channels 204, and a plurality of memory dies 206. In an example, each superblock includes at least one set of memory pages, where each page is distributed on a distinct one of the plurality of memory dies 206, has the same die, plane, block, and page designations, and is accessed via a distinct channel of the distinct memory die 206. In another example, each superblock includes at least one set of memory blocks, where each memory block is distributed on a distinct one of the plurality of memory dies 206 includes a plurality of pages, has the same die, plane, and block designations, and is accessed via a distinct channel of the distinct memory die 206. The memory device 240 stores information of an ordered list of superblocks in a cache of the memory device 240. In some embodiments, the cache is managed by a host driver of the host device 220, and called a host managed cache (HMC).

In some embodiments, the memory device 240 includes a single-level cell (SLC) NAND flash memory chip, and each memory cell stores a single data bit. In some embodiments, the memory device 240 includes a multi-level cell (MLC) NAND flash memory chip, and each memory cell of the MLC NAND flash memory chip stores 2 data bits. In an example, each memory cell of a triple-level cell (TLC) NAND flash memory chip stores 3 data bits. In another example, each memory cell of a quad-level cell (QLC) NAND flash memory chip stores 4 data bits. In yet another example, each memory cell of a penta-level cell (PLC) NAND flash memory chip stores 5 data bits. In some embodiments, each memory cell can store any suitable number of data bits. Compared with the non-SLC NAND flash memory chips (e.g., MLC SSD, TLC SSD, QLC SSD, PLC SSD), the SSD that has SLC NAND flash memory chips operates with a higher speed, a higher reliability, and a longer lifespan, and however, has a lower device density and a higher price.

Each memory channel 204 is coupled to a respective channel controller 214 (e.g., controller 214A, 214B, or 214N) configured to control internal and external requests to access memory cells in the respective memory channel 204. In some embodiments, each memory package 206 (e.g., each memory die) corresponds to a respective queue 216 (e.g., queue 216A, 216B, or 216N) of memory access requests. In some embodiments, each memory channel 204 corresponds to a respective queue 216 of memory access requests. Further, in some embodiments, each memory channel 204 corresponds to a distinct and different queue 216 of memory access requests. In some embodiments, a subset (less than all) of the plurality of memory channels 204 corresponds to a distinct queue 216 of memory access requests. In some embodiments, all of the plurality of memory channels 204 of the memory device 240 corresponds to a single queue 216 of memory access requests. Each memory access request is optionally received internally from the memory device 240 to manage the respective memory channel 204 or externally from the host device 220 to write or read data stored in the respective channel 204. Specifically, each memory access request includes one of: a system write request that is received from the memory device 240 to write to the respective memory channel 204, a system read request that is received from the memory device 240 to read from the respective memory channel 204, a host write request that originates from the host device 220 to write to the respective memory channel 204, and a host read request that is received from the host device 220 to read from the respective memory channel 204. It is noted that system read requests (also called background read requests or non-host read requests) and system write requests are dispatched by a memory controller to implement internal memory management functions including, but are not limited to, garbage collection, wear levelling, read disturb mitigation, memory snapshot capturing, memory mirroring, caching, and memory sparing.

In some embodiments, in addition to the channel controllers 214, the controller 202 further includes a local memory processor 218, a host interface controller 222, an SRAM buffer 224, and a DRAM controller 226. The local memory processor 218 accesses the plurality of memory channels 204 based on the one or more queues 216 of memory access requests. In some embodiments, the local memory processor 218 writes into and read from the plurality of memory channels 204 on a memory block basis. Data of one or more memory blocks are written into, or read from, the plurality of channels jointly. No data in the same memory block is written concurrently via more than one operation. Each memory block optionally corresponds to one or more memory pages. In an example, each memory block to be written or read jointly in the plurality of memory channels 204 has a size of 16 KB (e.g., one memory page). In another example, each memory block to be written or read jointly in the plurality of memory channels 204 has a size of 64 KB (e.g., four memory pages). In some embodiments, each page has 16 KB user data and 2 KB metadata. Additionally, a number of memory blocks to be accessed jointly and a size of each memory block are configurable for each of the system read, host read, system write, and host write operations.

In some embodiments, the local memory processor 218 stores data to be written into, or read from, each memory block in the plurality of memory channels 204 in an SRAM buffer 224 of the controller 202. Alternatively, in some embodiments, the local memory processor 218 stores data to be written into, or read from, each memory block in the plurality of memory channels 204 in a DRAM buffer 228A that is included in memory device 200, e.g., by way of the DRAM controller 226. Alternatively, in some embodiments, the local memory processor 218 stores data to be written into, or read from, each memory block in the plurality of memory channels 204 in a DRAM buffer 228B that is main memory used by the processor module 102 (FIG. 1). The local memory processor 218 of the controller 202 accesses the DRAM buffer 228B via the host interface controller 222.

In some embodiments, the memory device 200 includes an integrity engine 230 (e.g., an LDPC engine) and registers 232 including a plurality of registers or SRAM cells or flip-flops and coupled to the integrity engine 230. The integrity engine 230 is coupled to the memory channels 204 via the channel controllers 214 and SRAM buffer 224. Specifically, in some embodiments, the integrity engine 230 has data path connections to the SRAM buffer 224, which is further connected to the channel controllers 214 via data paths that are controlled by the local memory processor 218. The integrity engine 230 is configured to verify data integrity for each coding block of the memory channels 204.

In some embodiments, the number of dies 206 included in each channel 204 of a memory device 240 (e.g., an SSD) has can vary based on one or more of target performance, capacity, and intended use case. For example, the memory controller 202 is coupled to a plurality of memory channels 204, and the number of channels ranges from 4 to 16, to facilitate simultaneous data transfers and parallel data processing with parallel read and write operations. In some embodiments, a consumer-grade SSD has 8 to 16 channels 204, and each channel 204 interfaces with 1 to 2 NAND flash chips 206. The exact number of channels can depend on the storage capacity of the SSD and the density of the NAND flash chips 206 used. Conversely, in some embodiments, an enterprise-grade SSD is applied in a data center or a server, and employs 2, 4, or more NAND flash chips 206 per channel 204. For instance, an enterprise SSD with a 16-channel controller 202 and 2 NAND flash chips 206 per channel 204 would have a total of 32 NAND flash chips 206. In some embodiments, the dies 206 associated with all of the plurality of channels 204 of the memory device 240 are integrated in a semiconductor package, thereby providing the memory device 240 (e.g., an SSD).

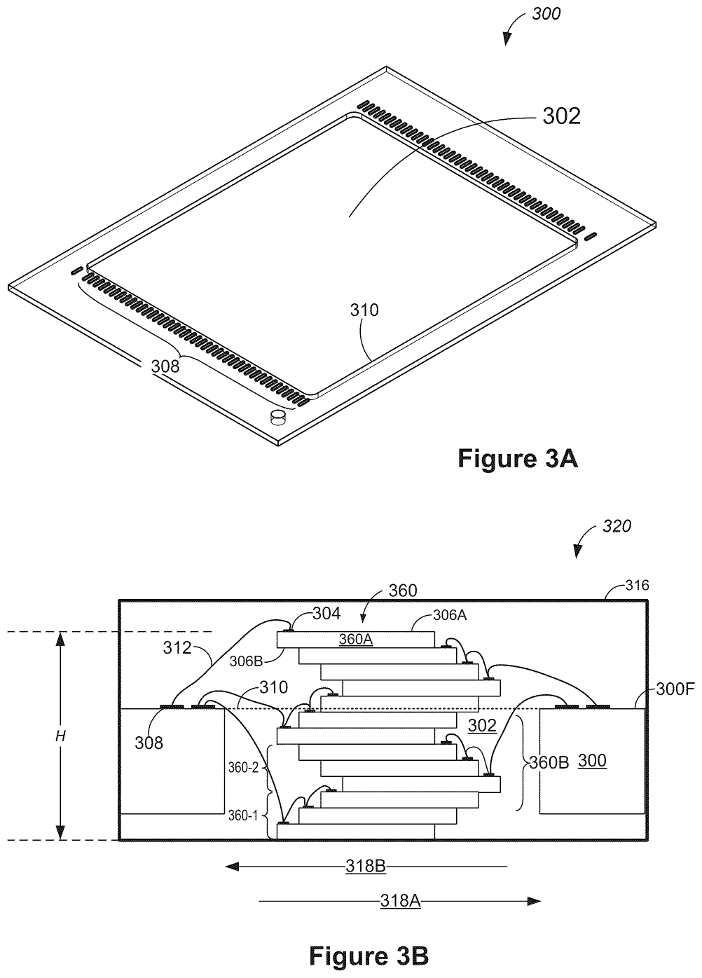

FIG. 3A is a perspective view of a device substrate 300 having a cutout opening 302 for receiving a stack of memory chips 360, in accordance with some embodiments, and FIG. 3B is a side view of a memory device 320 that is formed based on the device substrate 300 shown in FIG. 3A, in accordance with some embodiments. The memory device 320 includes a plurality of memory chips 360 that are stacked on top of one another to form a stack of memory chips 360. The stack of memory chips 360 includes a first memory chip 360A. The first memory chip 360A further includes a chip pad 304 formed on a first surface 306A of the first memory chip 360A. A device substrate 300 includes a plurality of substrate pads 308. The plurality of substrate pads 308 are formed on a front surface 300F of the device substrate 300. The front surface 300F has a front opening 310. The device substrate 300 receives the stack of memory chips 360 via the front opening 310 of the front surface 300F. A conductive wire 312 is coupled to the front surface 300F and the stack of memory chips 360, and is configure to couple the chip pad 304 and one of the plurality of substrate pads 308 electrically.

In some embodiments, the memory device 320 includes the memory device 240 (FIG. 2). In some embodiments, the memory device 320 includes a subset of the memory device 240 (FIG. 2). In some embodiments, the stack of memory chips 360 are identical to each other. In some embodiments, at least one memory chip 360 is distinct from a remainder of the stack of memory chips 360. In some embodiments, the first memory chip 360A includes an NAND die including a plurality of NAND memory cells. In some embodiments, each and every memory chip of the stack of memory chips 360 is an NAND die including a plurality of NAND memory cells. In some embodiments, one of the stack of memory chips 360 is a memory die 206 (FIG. 2). In some embodiments, one of the stack of memory chips 360 includes a memory controller 202 (FIG. 2).

Referring to FIG. 3A, in some embodiments, the front opening 310 of the front surface 300F corresponds to the cutout opening 302 in which substrate material located under the front opening 310 is entirely removed along a thickness of the device substrate 300, and forms a window space on the device substrate 300. In other words, referring to FIG. 3B, the cutout opening 302 goes through an entire thickness of the device substrate 300 and has a top edge defined by the front opening 310 of the front surface 300F, and the stack of memory chips 360 is disposed in the cutout opening 302 and surrounded by the device substrate 300. A thickness of one or more memory chips 360B overlaps a thickness of the device substrate 300.

In some embodiments, the first memory chip 360A further includes a second surface 306B opposing the first surface 306A, and both the first surface 306A and the second surface 306B are substantially parallel to the front surface 300F of the device substrate 300.

Referring to FIG. 3B, in some embodiments, the stack of memory chips 360 includes a first set of memory chips 360-1, and the first set of memory chips 360-1, when stacked upward, are spatially offset with one another along a first direction 318A in a stair-like manner. The first direction 318A may be parallel to the front surface 300F of the device substrate 300 and perpendicular to a top edge of the cutout opening 302. Further, in some embodiments, the stack of memory chips 360 further includes a second set of memory chips 360-2 attached to the first set of memory chips 360-1, and the second set of memory chips 360-2, when stacked upward, are spatially offset with one another along a second direction 318B in a stair-like manner, and the second direction 318B is opposite to the first direction 318A. Further, in some embodiments, each of the first set of memory chips 360-1 and the second set of memory chips 360-2 includes at least one respective chip pad 304 that is not covered by any memory chip 360. The at least one respective chip pads 304 of the first set of memory chips 360-1 and the at least one respective chip pads 304 of the second set of memory chips 360-2 are disposed in proximity to two opposite edges of the front opening of the front surface of the device substrate, respectively.

In some embodiments not shown, the front opening 310 of the front surface 300F includes three edges, and two of the three edges are connected to an edge of the device substrate 300. Stated another way, a side of the cutout opening 302 overlaps an edge of the device substrate 300. The cutout opening 302 is not limited to be fully enclosed in the device substrate 300. Alternatively, in some embodiments not shown, the front opening 310 of the front surface 300F includes two edges connected to edges of the device substrate 300. The stack of memory devices 360 are disposed at a corner of the device substrate 300. The cavity may miss two side walls while have only two side walls.

The stack of memory chips 360 coupled to the device substrate 300 may be disposed in a package 316 to at least partially form the memory device 320. In some embodiments, the memory device 320 further includes a printed circuit board (PCB) where the package 316 and the memory controller 202 are mounted, and the PCB includes a plurality of planar wires electrically coupling the stack of memory chips in the package 316 to the memory controller 202, forming a solid-state device (SSD) in which the stack of memory chips 360 is configured to be controlled by the memory controller 202. Alternatively, in some embodiments, the memory controller 202 is integrated in the package 316. The memory controller 202 either replaces one of the stack of memory chips 360 or is disposed on the front surface 300F of the device substrate 300. The package 316 of the memory device 240 contains the memory chips 360 and the memory controller 202, and is further disposed on a PCB (e.g., a motherboard of a system module 100).

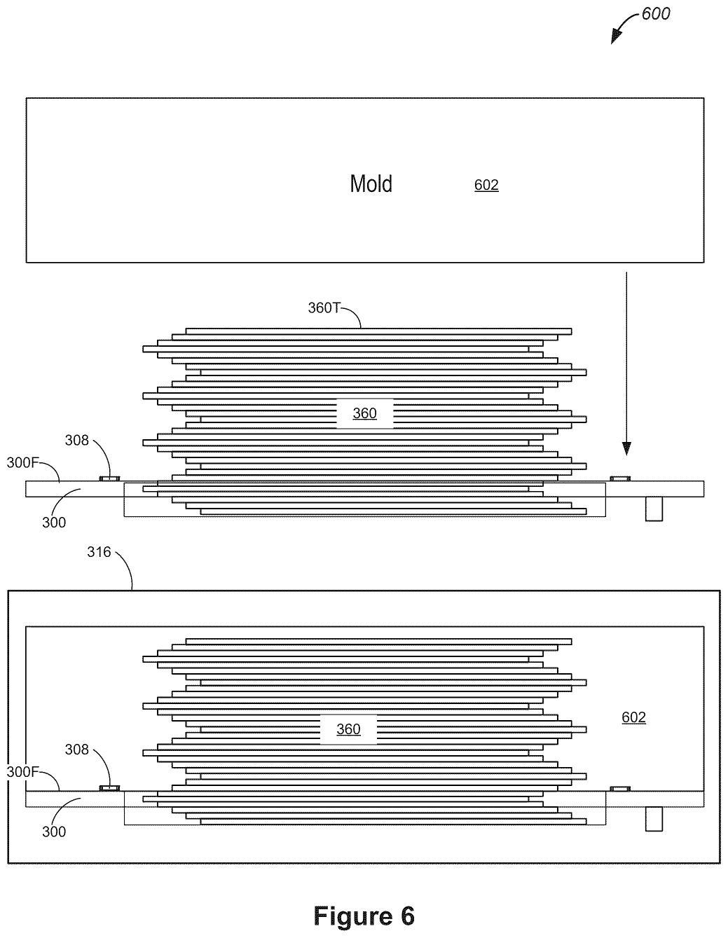

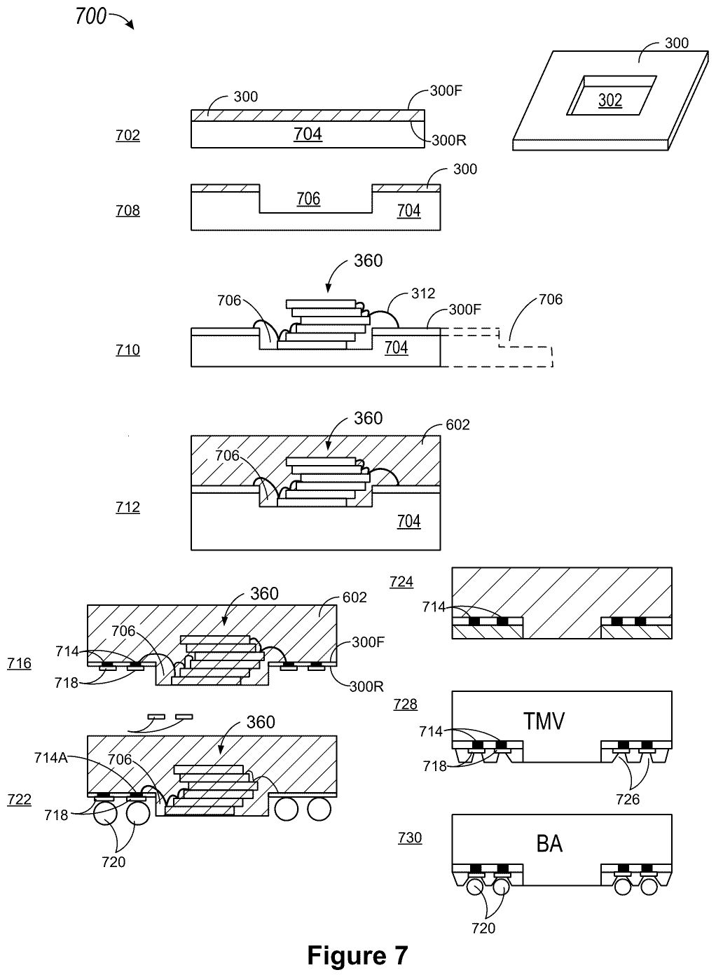

In some embodiments, the package 316 includes a support component 704, a molding component 602, or both. More details of the support component 704 and the molding component 602 are provided below with reference to FIGS. 6 and 7.

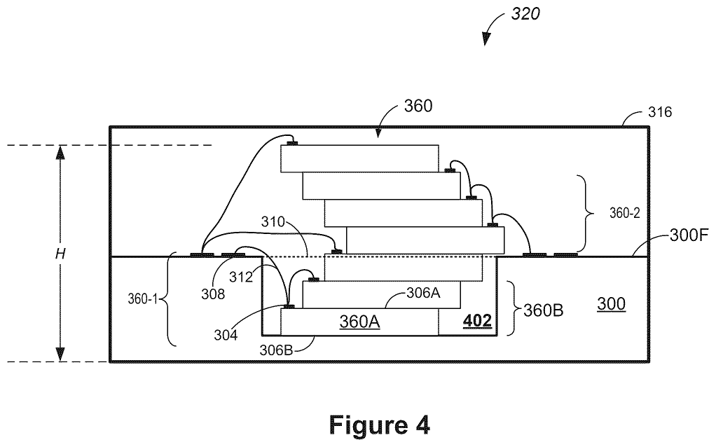

FIG. 4 is a cross sectional view of a memory module 400 that includes a device substrate 300 having a recess 402 for receiving a stack of memory chips 360, in accordance with some embodiments. A plurality of memory chips 360 are stacked on top of one another to form a stack of memory chips 360. The stack of memory chips 360 includes including a first memory chip 360A. The first memory chip 360A further includes a chip pad 304 formed on a first surface 306A of the first memory chip 360A. A device substrate 300 includes a plurality of substrate pads 308. The plurality of substrate pads 308 are formed on a front surface 300F of the device substrate 300. The front surface 300F has a front opening 310. The device substrate 300 receives the stack of memory chips 360 via the front opening 310 of the front surface 300F.

In some embodiments, the front opening 310 of the front surface 300F corresponds to the recess 402 in which substrate material located under the front opening 310 is partially removed along a thickness of the device substrate 300, and forms a cavity on the device substrate 300. In other words, the recess 402 having a top edge defined by the front opening 310 of the front surface 300F, and the stack of memory chips are partially disposed in the recess 402. One or more memory chips 360B may sit in the recess, having their top surfaces under the front opening 310 of the front surface 300F of the device substrate 300. A thickness of the one or more memory chips 360B overlaps a thickness of the device substrate 300.

In some embodiments, the first memory chip 360A sits on, and contacts, a bottom surface of the recess 402. A depth of the recess 402 is less than a thickness of the device substrate 300. In an example, the depth of the recess 402 is greater than a thickness of the first memory chip 360A, and more than one memory chip 360 sits in the recess 402. In another example, the depth of the recess 402 is less than a thickness of the first memory chip 360A, and only the first memory chip 360A partially sits in the recess 402.

In some embodiments not shown, the front opening 310 of the front surface 300F includes three edges, and two of the three edges are connected to an edge of the device substrate 300. A side of the recess 402 overlaps an edge of the device substrate 300. The recess 402 may miss a side wall and have only three side walls and a bottom. Alternatively, in some embodiments not shown, the front opening 310 of the front surface 300F includes two edges connected to edges of the device substrate 300. Two sides of the recess 402 overlap edges of the device substrate 300, and the stack of memory devices 360 are disposed at a corner area of the device substrate 300. The recess 402 may miss two side walls while having only two side walls and a bottom.

Referring to FIGS. 3B and 4, in some embodiments, a front surface 300F of the device substrate 300 creates a chip assembly area corresponding to a recess 402 (also called a cavity) or a cutout opening 302 (also called a window). Compared with leaving the stack of memory dies 360 sitting on the front surface 300F of the device substrate 300, application of the recess 402 or the cutout opening 302 reduces an overall height H of a memory module to be placed in a package 316 to form the memory device 320, so does it reduce a greatest length L of the wires 312 coupled between substrate pads 308 of the device substrate 300 and chip pads 304 of the memory chips 360.

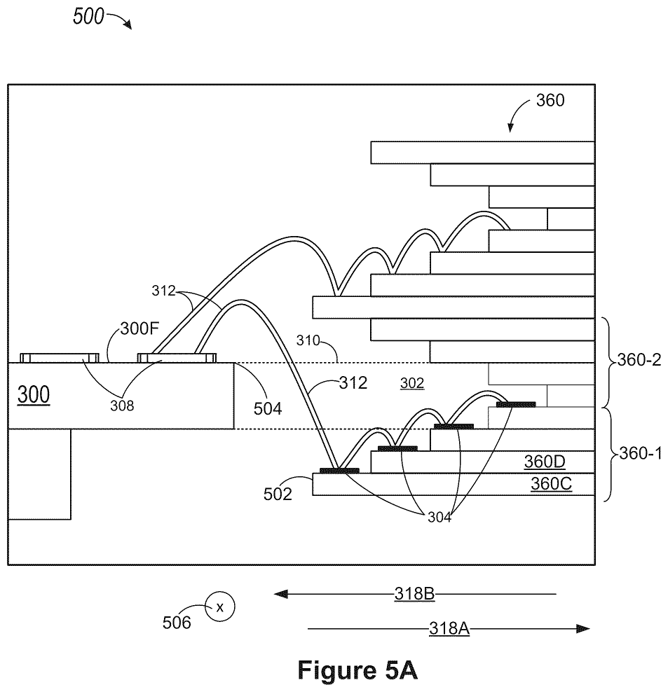

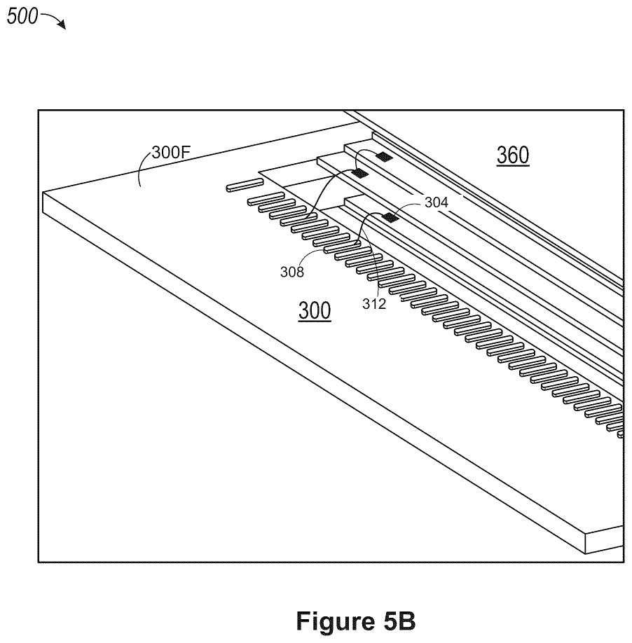

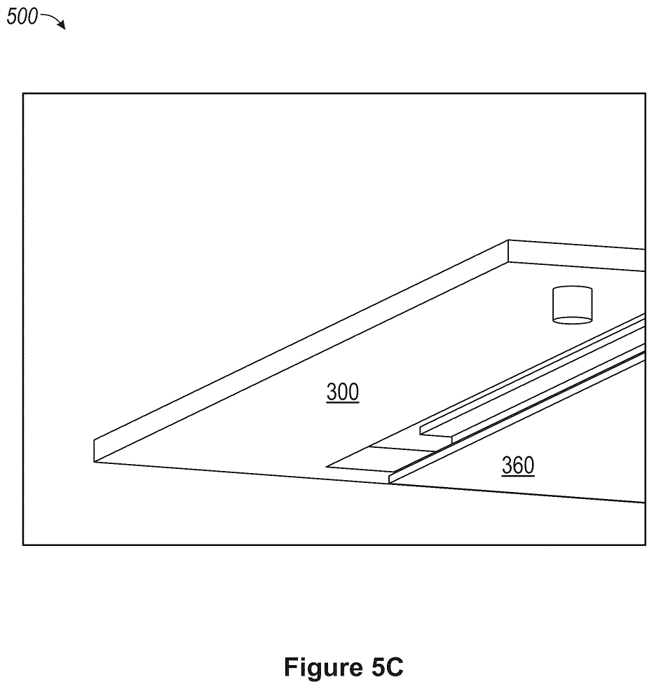

FIGS. 5A, 5B, and 5C are a cross sectional view, a top perspective view, and a bottom perspective view of an example interface region 500 of a memory device 320, in accordance with some embodiments, respectively. The interface region 500 is formed between a cutout opening 302 of a device substrate 300 and a stack of memory chips 360. The memory device 320 includes a stack of memory chips 360. The stack of memory chips 360 includes a first set of memory chips 360-1, and the first set of memory chips 360-1, when stacked upward, are spatially offset with one another along a first direction 318A in a stair-like manner. The first direction 318A may be parallel to the front surface 300F of the device substrate 300 and perpendicular to a top edge of the cutout opening 302. Further, in some embodiments, the stack of memory chips 360 further includes a second set of memory chips 360-2 attached to the first set of memory chips 360-1, and the second set of memory chips 360-2, when stacked upward, are spatially offset with one another along a second direction 318B in a stair-like manner.

In some embodiments, one of the first set of memory chips 360-1 (e.g., chip 360C in FIG. 5A) includes at least one respective chip pad 304 that is not covered by any memory chip 360, and the at least one respective chip pad 304 is coupled to at least one respective substrate pad 308 on the front surface 300F of the device substrate 300 via at least one respective conductive wire 312. In some embodiments, the at least one respective chip pad 304 includes a plurality of chip pads 304 (e.g., a row of chip pads 304 arranged perpendicular to a cross section shown in FIG. 5A).

Referring to FIG. 5A, in some embodiments, each of the first set of memory chips 360-1 has a respective chip side 502 that is disposed in proximity to a first edge 504 of a front opening 310 of the front surface 300F of the device substrate 300. Each of the first set of memory chips 360-1 includes a respective chip pad 304 located on a top surface of the respective memory chip 360-1 in proximity to the first edge 504. The respective chip pad 304 may be coupled to a corresponding substrate pad 308 located on the front surface 300F of the device substrate 300 and in proximity to the first edge 504 via a respective wire 312. Alternatively, in an example, a respective chip pad 304 of a memory chip (e.g., chip 360C) in the first set of memory chips 360-1 may be coupled to another respective chip pad 304 of a memory chip 360D in the first set of memory chips 360-1.

In some embodiments not shown, the first set of memory chips 360-1, when stacked upward, are spatially offset with one another along a third direction 506 in a stair-like manner, and the third direction is perpendicular to the first direction 318A. The third direction 506 may be perpendicular to a cross section shown in FIG. 5A. Additionally, in some embodiments, one of the first set of memory chips 360-1 (e.g., chip 360E) includes two chip pads 304 that are disposed in proximity to two connected edges of the respective memory chip 360-1 and not covered by any memory chip 360, and the two chip pads 304 are coupled to two substrate pads 308 on the front surface 300F of the device substrate 300 via two conductive wires 312, respectively.

FIG. 6 illustrates an example process 600 of protecting a memory device 320 with a molding component 602, in accordance with some embodiments. The molding component 602 at least partially covers the front surface 300F of the device substrate 300 and a top surface 360T of the stack of memory chips 360, conformally filling a space between the device substrate 300 and the stack of memory chips 360. The space is part of the cutout opening 302 (FIG. 3B) or the recess 402 (FIG. 4) of the device substrate 300. The molding component 602 provides mechanical support to the stack of memory devices 360 after the memory devices 360 are coupled to the device substrate 300, so does it provide a robust shield to the memory devices 320 against environmental factors such as moisture, dust, and physical damage.

In some embodiments, the molding component 602 includes a molding material (e.g., epoxy or resin) that is selected for its insulating properties, thermal stability, and mechanical strength. Examples of the molding material includes, but are not limited to, epoxy, resin, silicone-based materials, and thermoplastic polymers (e.g., polyimides and liquid crystal polymers). By forming a protective layer, the molding component 602 ensures the longevity and reliability of the memory device 320, safeguarding its performance in various electronic applications.

FIG. 7 is a flow diagram of an example process 700 of forming a memory device 320 having a cutout opening 302, in accordance with some embodiments. A device substrate 300 is coupled (operation 702) to a support component 704 (also called a carrier). For example, the device substrate 300 is attached to the support component 704 via a rear surface 300R of the device substrate 300. The rear surface 300R is opposite to the front surface 300F. In an example, the support component 704 is made of glass, silicon, or a molding material. In some situations, the support component 704 is a rigid material. In some embodiments, a recess 706 is formed (operation 708) on the device substrate 300 and the support component 704, thereby providing a cutout opening 302 (FIGS. 3A and 3B). A photo resist layer may be used as a mask to define the recess 706. Alternatively, in some embodiments not shown, after the cutout opening 302 is formed on the device substrate 300, the device substrate 300 is coupled to the support component 704, which is further processed to form the recess 706 aligned with the cutout opening 302.

The stack of memory chips 360 are disposed (operation 710) to sit in the recess 706, i.e., a bottom surface of the stack of memory chips 360 comes into contact with a bottom surface of the recess 706. Wires 312 are connected between a subset of the memory chips 360 and the device substrate 300 or among the memory chips 360. From a different perspective, the support component 704 is part of the device substrate 300, and the recess 706 is formed on the device substrate 300 and represents the recess 402 (FIG. 4). The stack of memory chips 360 is partially sits inside the recess 706 and below a level of the front surface 300F, and partially rises beyond the level of the front surface 300F. In an example, the recess 706 has a depth of 1 mm, and the stack of memory chips 360 is 2 mm high, having a bottom half inside the recess 706 and an upper half above the front surface 300F. In some embodiments, a recess 706′ is formed on an edge or a corner of the device substrate 300.

Further, in some embodiments, a molding material is applied (operation 712) to form a molding component 602 at least partially covers the front surface 300F of the device substrate 300 and a top surface 360T of the stack of memory chips 360, conformally filling a space between the device substrate 300 and the stack of memory chips 360. In some embodiments, the molding material flows and fills the recess 706 down to the bottom surface of the recess 706 before it is hardened.

In some embodiments, the device substrate 300 includes a plurality of conductive vias 714, and each conductive via 714 extends throughout a thickness of the device substrate 300. The support component 704 (e.g., made of glass) is removed (operation 716) to expose conductive pads 718 coupled to the plurality of conductive vias 714. In some embodiments, a first via 714A that extends throughout a thickness of the device substrate 300 and from the front surface 300F to a rear surface 300R of the device substrate 300 opposite the front surface 300F. The first via 714A is electrically coupled to the chip pad 304 and the one of the plurality of substrate pads 308 (FIGS. 3B and 4).

In some embodiments, a solder ball 720 may be applied (operation 722) onto a conductive pad 718, facilitating coupling the memory device 320 to other electronic components (e.g., onto a PCB). The solder ball 720 may have a diameter greater than a depth of the recess 706, and can come into contact with conductive pads disposed on a surface of another electronic component directly without being blocked by the molding material or the memory chips 360 in the recess 706.

Alternatively, in some embodiments not shown, a plurality of conductive vias are formed in the device substrate 300 and the support component 704. Each conductive via extends throughout a thickness of the device substrate 300 and a thickness of the support component 704. Under these circumstances, the support component 704 may be thinned before the plurality of conductive vias 714 are formed in the support component 704.

Conversely, in some embodiments, the device substrate 300 includes a plurality of conductive vias 714. The support component 704 may be (operation 724) thinned. Independently of whether the support component 704 is thinned or not, access openings 726 are opened (operation 728) on the support components 704 to access the conductive pads 718 coupled to the plurality of conductive vias 714. A solder ball 720 may be placed (operation 730) into an access opening 726 and come onto contact with a conductive pad 718, thereby facilitating coupling the memory device 320 to other electronic components (e.g., onto a PCB).

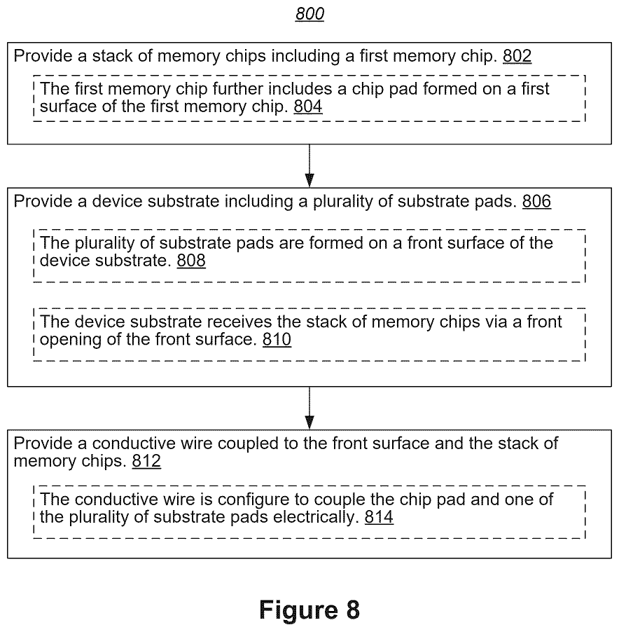

FIG. 8 is a flow diagram of an example method 800 for providing a memory device 320, in accordance with some embodiments. In accordance with the method 800, a stack of memory chips 360 including a first memory chip is provided (operation 802). The first memory chip further includes (operation 804) a chip pad 304 formed on a first surface of the first memory chip 360A. In some embodiments, the first memory chip 360A includes an NAND die including a plurality of NAND memory cells. A device substrate 300 including a plurality of substrate pads 308 is provided (operation 806). The plurality of substrate pads 308 are formed (operation 808) on a front surface 300F of the device substrate 300. The front surface 300F has a front opening 310, and the device substrate 300 receives (operation 810) the stack of memory chips 360 via the front opening 310 of the front surface 300F. A conductive wire 312 is provided (operation 812) to be coupled to the front surface 300F and the stack of memory chips 360. The conductive wire 312 is configure (operation 814) to couple the chip pad 304 and one of the plurality of substrate pads 308 electrically.

In some embodiments (FIG. 4), a recess 402 is formed on the device substrate 300. The recess 402 has a top edge defined by the front opening 310 of the front surface 300F, and the stack of memory chips 360 are partially disposed in the recess 402. Further, in some embodiments, the first memory chip 360A sits on, and contacts, a bottom surface of the recess 402. Alternatively, in some embodiments (FIG. 3B), a cutout opening 302 is formed on the device substrate 300. The cutout opening 302 that goes through an entire thickness of the device substrate 300 and has a top edge defined by the front opening 310 of the front surface 300F, and the stack of memory chips 360 is disposed in the cutout opening 302 and surrounded by the device substrate 300. Stated another way, a thickness of the device substrate 300 in the front opening 310 is 0 for the cutout opening 302 and greater than 0 for the recess 402, and is smaller than a thickness of a remainder area distinct from the front opening 310.

In some embodiments, the stack of memory chips 360 includes a first set of memory chips 360-1, and the first set of memory chips 360-1 are spatially offset with one another along a first direction 318A (FIG. 3B) in a stair-like manner. Further, in some embodiments, the stack of memory chips 360 further includes a second set of memory chips 360-2 attached to the first set of memory chips 360-1, and the second set of memory chips 360-2 are spatially offset with one another along a second direction 318B (FIG. 3B) in a stair-like manner, the second direction opposite to the first direction. Additionally, in some embodiments, each of the first set of memory chips 360-1 and the second set of memory chips 360-2 includes at least one respective chip pad 304 that is not covered by any memory chip. The at least one respective chip pads of the first set of memory chips 360-1 and the at least one respective chip pads of the second set of memory chips 360-2 are disposed in proximity to two opposite edges of the front opening 310 of the front surface 300F of the device substrate 300, respectively.

In some embodiments, one of the first set of memory chips 360-1 includes at least one respective chip pad 304 that is not covered by any memory chip, and the at least one respective chip pad 304 is coupled to at least one respective substrate pad on the front surface 300F of the device substrate 300 via at least one respective conductive wire.

In some embodiments, the first set of memory chips 360-1 are spatially offset with one another along a third direction in a stair-like manner, and the third direction is perpendicular to the first direction. Further, in some embodiments, each of the first set of memory chips 360-1 includes two chip pads that are disposed in proximity to two connected edges of the respective memory chip and not covered by any memory chip, and the two chip pads are coupled to two substrate pads 308 on the front surface 300F of the device substrate 300 via two conductive wires, respectively.

In some embodiments, a molding component 602 is provided. The molding component 602 at least partially covers the front surface 300F of the device substrate 300 and a top surface of the stack of memory chips 360 and conformally fills a space between the device substrate 300 and the stack of memory chips 360.

In some embodiments, a support component 704 is provided. The support component 704 is attached to a rear surface 300R of the device substrate 300 and a bottom surface of the stack of memory chips 360. The rear surface 300R of the device substrate 300 is opposite to the front surface 300F. Further, in some embodiments, a plurality of conductive vias are formed. Each conductive via extends throughout a thickness of the device substrate 300 and a thickness of the support component 704, and is exposed from a rear surface 300R of the support component 704. In some embodiments, the support component 704 includes a rigid material (e.g., glass, silicon).

In some embodiments, a plurality of conductive vias, are formed with each conductive via extending throughout a thickness of the device substrate 300 and from the front surface 300F to a rear surface 300R of the device substrate 300 opposite the front surface 300F.

In some embodiments, a first via 718A (FIG. 7) is formed to extend throughout a thickness of the device substrate 300 and from the front surface 300F to a rear surface 300R of the device substrate 300 opposite the front surface 300F. The first via 718A is electrically coupled to the chip pad 304 and the one of the plurality of substrate pads 308.

In some embodiments, the memory device 320 includes a printed circuit board (PCB) where a memory controller 202 is mounted, and the PCB includes a plurality of planar wires electrically coupling the stack of memory chips 360 to the memory controller, forming a solid-state device (SSD) in which the stack of memory chips 360 is configured to be controlled by the memory controller.

In some embodiments, the front opening 310 of the front surface 300F is formed on an edge of the device substrate 300. The front opening 310 includes three edges, and two of the three edges are connected to an edge of the device substrate 300.

In some implementations of this application, a method is provided to form a stack of memory chips 360 including a first memory chip and a remainder of the stack. The first memory chip has a first surface on which the remainder of the stack is mechanically coupled, and the first surface of the first memory chip includes a conductive chip pad. A device substrate 300 having a front surface 300F and a rear surface 300R opposing the front surface 300F is provided. The front surface 300F has a cutout opening 302 for receiving the stack of memory chips 360, and the front surface 300F of the device substrate 300 includes a plurality of conductive substrate pads 308 surrounding the cutout opening 302 of the front surface 300F. A first conductive wire 312 is coupled to both the front surface 300F and the stack of memory chip. The first conductive wire 312 is attached to the conductive chip pad 304 of the first memory chip and one of the plurality of conductive substrate pads 308 of the device substrate 300. A thickness of the device substrate 300 at least partially overlaps a thickness of the stack of memory chips 360, and a footprint of the stack of the memory chips 360 at least partially overlaps the cutout opening 302 of the front surface 300F of the device substrate 300.

In some implementations of this application, a method is provided to providing a stack of semiconductor chips including a first memory chip 360A, a device substrate 300 including a plurality of substrate pads 308, and a conductive wire 312 coupled to the front surface 300F and the stack of semiconductor chips. The first memory chip 360A further includes a chip pad 304 formed on a first surface of the first memory chip 360A. The plurality of substrate pads 308 are formed on a front surface 300F of the device substrate 300, and the front surface 300F has a front opening 310, and wherein the device substrate 300 receives the stack of semiconductor chips via the front opening 310 of the front surface 300F. The conductive wire 312 is configure to couple the chip pad 304 and one of the plurality of substrate pads 308 electrically.

In some implementations of this application, a method includes providing a device substrate 300 including a plurality of substrate pads 308, removing a portion of a device substrate 300 to create one of a recess 402 and a cutout opening 302, and providing a stack of chips including a first memory chip 360A. The plurality of substrate pads 308 are formed on a front surface 300F of the device substrate 300, and the front surface 300F has a front opening 310. The first memory chip 360A further includes a chip pad 304 formed on a first surface of the first memory chip 360A. The method further includes receiving the stack of memory chips 360 via the front opening 310 of the front surface 300F to partially fill the portion of the removed portion of the device substrate 300, and applying a conductive wire 312 to couple the chip pad 304 of the first memory chip 360A and one of the plurality of substrate pads 308 of the device substrate 300.

Each of the above identified elements may be stored in one or more of the previously mentioned memory devices, and corresponds to a set of instructions for performing a function described above. The above identified modules or programs (i.e., sets of instructions) need not be implemented as separate software programs, procedures, modules or data structures, and thus various subsets of these modules may be combined or otherwise re-arranged in various embodiments. In some embodiments, the memory, optionally, stores a subset of the modules and data structures identified above. Furthermore, the memory, optionally, stores additional modules and data structures not described above.

The terminology used in the description of the various described implementations herein is for the purpose of describing particular implementations only and is not intended to be limiting. As used in the description of the various described implementations and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. Additionally, it will be understood that, although the terms “first,” “second,” etc. may be used herein to describe various elements, these elements should not be limited by these terms. These terms are only used to distinguish one element from another.

As used herein, the term “if” is, optionally, construed to mean “when” or “upon” or “in response to determining” or “in response to detecting” or “in accordance with a determination that,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event]” or “in accordance with a determination that [a stated condition or event] is detected,” depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art.

Although various drawings illustrate a number of logical stages in a particular order, stages that are not order dependent may be reordered and other stages may be combined or broken out. While some reordering or other groupings are specifically mentioned, others will be obvious to those of ordinary skill in the art, so the ordering and groupings presented herein are not an exhaustive list of alternatives. Moreover, it should be recognized that the stages can be implemented in hardware, firmware, software or any combination thereof.

What is claimed is:

1. A memory device, comprising:
a stack of memory chips including a first memory chip, wherein the first memory chip further includes a chip pad formed on a first surface of the first memory chip;
a device substrate including a plurality of substrate pads, wherein the plurality of substrate pads are formed on a front surface of the device substrate, and the front surface has a front opening, and wherein the device substrate receives the stack of memory chips via the front opening of the front surface; and
a conductive wire coupled to the front surface and the stack of memory chips, wherein the conductive wire is configure to couple the chip pad and one of the plurality of substrate pads electrically.

2. The memory device of claim 1, wherein the device substrate includes a recess having a top edge defined by the front opening of the front surface, and the stack of memory chips are partially disposed in the recess.

3. The memory device of claim 2, wherein the first memory chip sits on, and contacts, a bottom surface of the recess.

4. The memory device of claim 1, wherein the device substrate includes a cutout opening that goes through an entire thickness of the device substrate and has a top edge defined by the front opening of the front surface, and the stack of memory chips is disposed in the cutout opening and surrounded by the device substrate.

5. The memory device of claim 1, wherein the stack of memory chips includes a first set of memory chips, and the first set of memory chips are spatially offset with one another along a first direction in a stair-like manner.

6. The memory device of claim 5, wherein the stack of memory chips further includes a second set of memory chips attached to the first set of memory chips, and the second set of memory chips are spatially offset with one another along a second direction in a stair-like manner, the second direction opposite to the first direction.

7. The memory device of claim 6, wherein:
each of the first set of memory chips and the second set of memory chips includes at least one respective chip pad that is not covered by any memory chip;
the at least one respective chip pads of the first set of memory chips and the at least one respective chip pads of the second set of memory chips are disposed in proximity to two opposite edges of the front opening of the front surface of the device substrate, respectively.

8. The memory device of claim 5, wherein:
one of the first set of memory chips includes at least one respective chip pad that is not covered by any memory chip, and the at least one respective chip pad is coupled to at least one respective substrate pad on the front surface of the device substrate via at least one respective conductive wire.

9. The memory device of claim 5, wherein the first set of memory chips are spatially offset with one another along a third direction in a stair-like manner, and the third direction is perpendicular to the first direction.

10. The memory device of claim 9, wherein:
each of the first set of memory chips includes two chip pads that are disposed in proximity to two connected edges of the respective memory chip and not covered by any memory chip, and the two chip pads are coupled to two substrate pads on the front surface of the device substrate via two conductive wires, respectively.

11. The memory device of claim 1, further comprising:
a molding component at least partially covering the front surface of the device substrate and a top surface of the stack of memory chips and conformally filling a space between the device substrate and the stack of memory chips.

12. The memory device of claim 1, further comprising:
a support component attached to a rear surface of the device substrate, which is opposite to the front surface, and a bottom surface of the stack of memory chips.

13. The memory device of claim 12, further comprising:
a plurality of conductive vias, each conductive via extending throughout a thickness of the device substrate and a thickness of the support component, each conductive via being exposed from a rear surface of the support component.

14. The memory device of claim 12, where the support component includes a rigid material.

15. The memory device of claim 1, further comprising:
a plurality of conductive vias, each conductive via extending throughout a thickness of the device substrate and from the front surface to a rear surface of the device substrate opposite the front surface.

16. The memory device of claim 1, further comprising:
a first via that extends throughout a thickness of the device substrate and from the front surface to a rear surface of the device substrate opposite the front surface, wherein the first via is electrically coupled to the chip pad and the one of the plurality of substrate pads.

17. The memory device of claim 1, wherein the first memory chip includes an NAND die including a plurality of NAND memory cells.

18. The memory device of claim 1, wherein the memory device includes a printed circuit board (PCB) where a memory controller is mounted, and the PCB includes a plurality of planar wires electrically coupling the stack of memory chips to the memory controller, forming a solid-state device (SSD) in which the stack of memory chips is configured to be controlled by the memory controller.

19. The memory device of claim 1, wherein the front opening of the front surface includes three edges, and two of the three edges are connected to an edge of the device substrate.

20. A method, comprising:
providing a device substrate including a plurality of substrate pads, wherein the plurality of substrate pads are formed on a front surface of the device substrate, and the front surface has a front opening;
removing a portion of a device substrate to create one of a recess and a cutout opening;
providing a stack of chips including a first memory chip, wherein the first memory chip further includes a chip pad formed on a first surface of the first memory chip;
receiving the stack of memory chips via the front opening of the front surface to partially fill the portion of the removed portion of the device substrate; and
applying a conductive wire to couple the chip pad of the first memory chip and one of the plurality of substrate pads of the device substrate.
